(19) United States
(12) Patent Application Publication
(10) Pub. No.: US 2001/0051933 A1
(43) Pub. Date: Dec. 13, 2001

(54) Prepaid utility service system

(76) Inventors: Robert H. Rowley, Amado, AZ (US); Jon F. Rowley, Amado, AZ (US)

Correspondence Address: Richard C. Litman, LITMAN LAW OFFICES, LTD., P.O. Box 15035, Arlington, VA, 22215, US

(21) Appl. No.: 09/864,205

(22) Filed: May 25, 2001

Related U.S. Application Data
(60) Provisional application No. 60/209,976, filed on Jun. 8, 2000.

(51) Int. Cl. G01R 11/56; G06F 17/00; G01R 21/133

(52) U.S. Cl. 705/412

(57) ABSTRACT

A prepay utility service system for facilitating prepayment of utility services by consumers. The prepay utility service system includes a client end portion, a processing center portion, and a client access portion. The client end portion serves to monitor usage of utility services. The processing center portion is communicatively connected to said client end portion for retrieving, storing and processing data obtained by the client end portion. The client access portion is communicatively interconnected to the processing center portion for enabling a remotely located client to create, modify, monitor, and terminate an account. There is also a second embodiment of the prepay utility service system, which utilizes a hub, a cell transmitter station and a remote transceiver unit.

### CROSS-REFERENCE TO RELATED APPLICATION

This application claims the benefit of U.S. Provisional Patent Application Ser. No. 60/209,976, filed Jun. 8, 2000.

### BACKGROUND OF THE INVENTION

1. Field of the Invention

The present invention relates generally to prepaid service systems and, more particularly, to a prepaid service for consumers for real-time consumption of gas, water, and/or electricity.

2. Description of Related Art

A customer of an electric company typically has an electric meter located at the customer's structure or site of distribution of electrical power. The customer's structure may be, for example, the customer's home or office. The electric meter is owned by the electric company and is installed in a standard meter box which holds the electric meter. The standard meter box is provided and owned by the customer.

The prior art include a number of references which disclose utility meters with associated electronics. For example, U.S. Pat. No. 4,803,632 issued on Feb. 7, 1989 to Larry H. Frew et al. describes an intelligent utility meter system which may include a basic meter unit having a 16 digit alphanumeric display, a CPU, and associated solid state circuitry which may be mounted on the outside of a house or building in a conventional meter location.

U.S. Pat. No. 5,383,113 issued on Jan. 17, 1995 to Peter J. Kight et al. describes a system and method for electronically providing customer services including payment of bills, financial analysis, and loans. A computerized payment system is described by which a consumer may instruct a service provider by telephone, computer terminal, or other telecommunications. The system includes a means to pay various bills without the consumer having to write a check for each bill.

U.S. Pat. No. 5,699,276 issued on Dec. 16, 1997 to Charles E. Roos describes a utility meter interface apparatus that is connected between a utility company and a home.

U.S. Pat. No. 5,884,288 issued on Mar. 16, 1999 to Shueueling Chang et al. describes a method and system for providing a fully automated electronic bill processing capability that is integrated with banking institutions and their customers.

U.S. Pat. No. 5,959,549 issued on Sep. 28, 1999 to Andreas Joanni Synesiou et al. describes a communal metering system. The metering system supplies electricity to consumer sites via metering sites which each comprise a number of separate metering and measurement devices and a common control unit.

U.S. Pat. No. 6,018,726 issued on Jan. 25, 2000 to Mihoji Tsumura describes a method and system of billing for information services in conjunction with utilities service.

However, none of the above inventions describe a computer-based method and system capable of enabling consumers to prepay for utility services, remotely. None of the above inventions describe a method and system for enabling consumers to remotely control the operation of utility meters. None of the above inventions describe a method and system for enabling consumers to remotely select a level of service to be obtained from a utility service company. None of the above inventions and patents, taken either singly or in combination, is seen to describe the instant invention as claimed.

### SUMMARY OF THE INVENTION

The invention is a prepay utility service system for facilitating prepayment of utility services by consumers. The prepay utility service system includes a client end portion, a processing center portion, and a client access portion. The client end portion serves to monitor usage of utility services. The processing center portion is communicatively connected to said client end portion for retrieving, storing and processing data obtained by the client end portion. The client access portion is communicatively interconnected to the processing center portion for enabling a remotely located client to create, modify, monitor, and terminate an account. There is also a second embodiment of the prepay utility service system, which utilizes a hub, a cell transmitter station and a remote transceiver unit.

Accordingly, it is a principal object of the invention to provide a remote computer-based system capable of enabling consumers to prepay for utility services.

It is another object of the invention to provide a remote computer-based system capable of enabling consumers to control the operation of utility meters.

It is a further object of the invention to provide a computer-based system for enabling consumers to remotely select the level of service to be provided by a utility service company.

It is an object of the invention to provide improved elements and arrangements thereof in an apparatus for the purposes described which is inexpensive, dependable and fully effective in accomplishing its intended purposes.

These and other objects of the present invention will become readily apparent upon further review of the following specification and drawings.

### BRIEF DESCRIPTION OF THE DRAWINGS

FIG. 1 is a block diagram of a pre-pay utility service system according to a first preferred embodiment of the present invention.

FIG. 2 is a block diagram of a pre-pay utility service system according to a second preferred embodiment of the present invention.

Similar reference characters denote corresponding features consistently throughout the attached drawings.

### DETAILED DESCRIPTION OF THE PREFERRED EMBODIMENTS

The present invention is a prepay utility service system 10 for facilitating prepayment of utility services by consumers. The prepay utility service system 10 also serves to detect real-time usage of utility services by consumers. The prepay utility service system 10 of the present invention may also be used for reading and remotely programming utility meters, preferably via a wireless data network. The prepay utility service system 10 is configured for enabling a consumer to remotely adjust the quantity of service to be provided by the prepay utility service system 10.

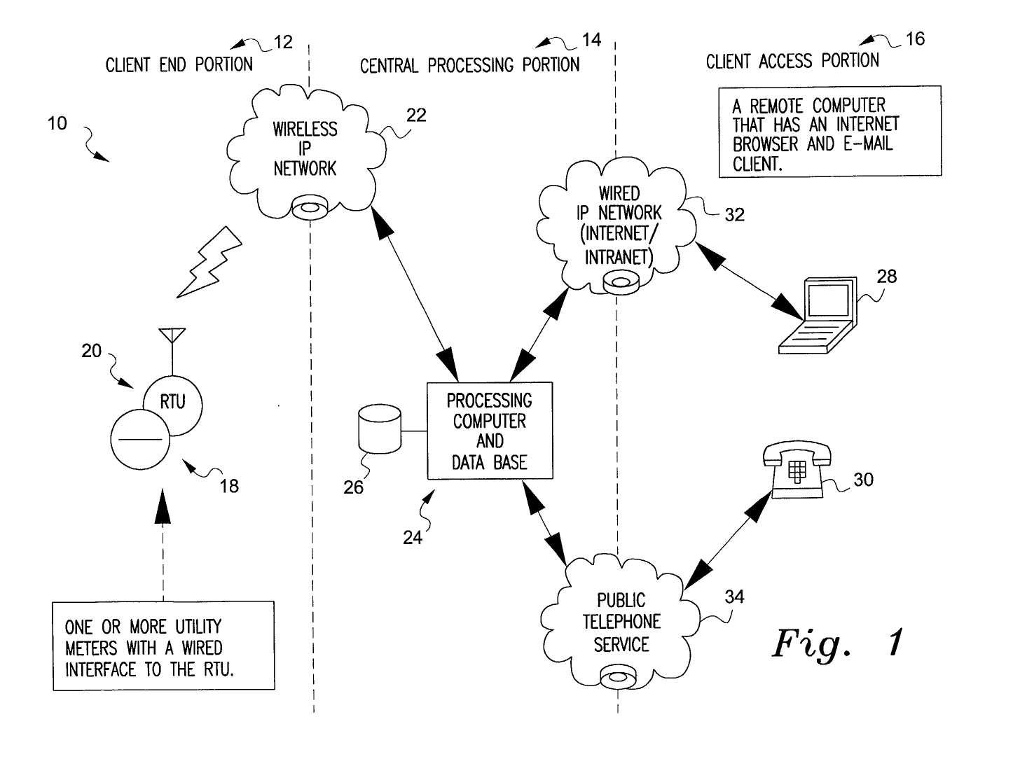

FIG. 1 shows a block diagram of a pre-pay utility service system 10 according to a first preferred embodiment of the invention. The prepay utility service system 10 is generally made up of a client end portion 12, a processing center portion 14, and a client access portion 16.

The client end portion 12 is a meter device installed anywhere in a wireless IP network. Preferably, the client end portion 12 includes a plurality of meters 18, a plurality of remote transceiver units (RTU) 20, and a first network 22. The first network 22 is a conventional wireless IP network for enabling a provider of utility services to read and program the meters 18 from a remote location. Each of the RTUs 20 is a conventional end user device, such as a radio modem, commonly used for transmitting data from the meter 18 to the first network 22. Each RTU 20 is also capable of two-way communication.

The processing center portion 14 generally serves as a fixed location where data may be retrieved, stored, and processed. The processing center portion 14 may include a computer processing unit 24 and a database 26. The computer processing unit 24 (sometimes referred to as the “clearing house service”) may be a computer that is owned and operated by a provider of utility services or may be a third party provider of the clearing house service. The database 26 is a conventional database that is used for storing various utility account data.

Conventional communications technology, that is known by those that are well schooled in the related art, may be used to interconnect the client end portion 12 to the processing center portion 14 for enabling a utility provider to perform any one of the following functions:

1. to control the operability of a meter 18,

2. to control the quantity services provided by a utility meters 18,

3. to determine the amount to be billed to a consumer for services consumed;

4. to substantially determine in real-time the level of services required by an existing consumer; and

5. to remotely connect and disconnect a utility service.

Conventional communication technology may be used to communicatively connect the client end portion 12 to the processing center portion 14 for enabling the processing center portion 14 to read and remotely program each of the meters 18.

The client access portion 16 is a conventional remotely-located, communications device for providing access to a client account. The client access portion 16 is communicatively interconnected to the processing center portion 14 by conventional communication technology for enabling utility consumers to access their account information stored in the processing center portion 14. The client access portion 16 may consist of a client computer 28, a telephone 30, a second network 32, and a third network 34. The second network 28 may be any one of several conventional wired Internet protocol (IP) networks, such as the Internet or an intranet network.

The client computer 28 may be any one of several conventional computers (e.g., a laptop computer) capable of being communicatively linked to an external device. The client computer 28 is communicatively linked to the second network 32 for enabling the client computer 28 to access utility accounts stored on the computer processing unit 24 and database 26.

The telephone 30 may be any one of several conventional telephones configured for transmitting and receiving telecommunications signals. The telephone 30 is communicatively linked by conventional communication technology to the third network 34 for enabling a consumer to access a utility service account stored by the processing center portion 14. The third network 34 is a conventional public telephone network for conducting telephony communications signals.

Accordingly, the client access portion 16 may be configured to enable utility consumers to create a new account, deposit funds in their account, view a remaining balance in an account, or cancel an account, each of these functions being achieved from a remote location relative to the central processing portion 14. Additionally, the present invention anticipates use of conventional technology for enabling a consumer to use a credit card, check, or automatic withdraw for purposes of advancing funds into a prepay utility account.

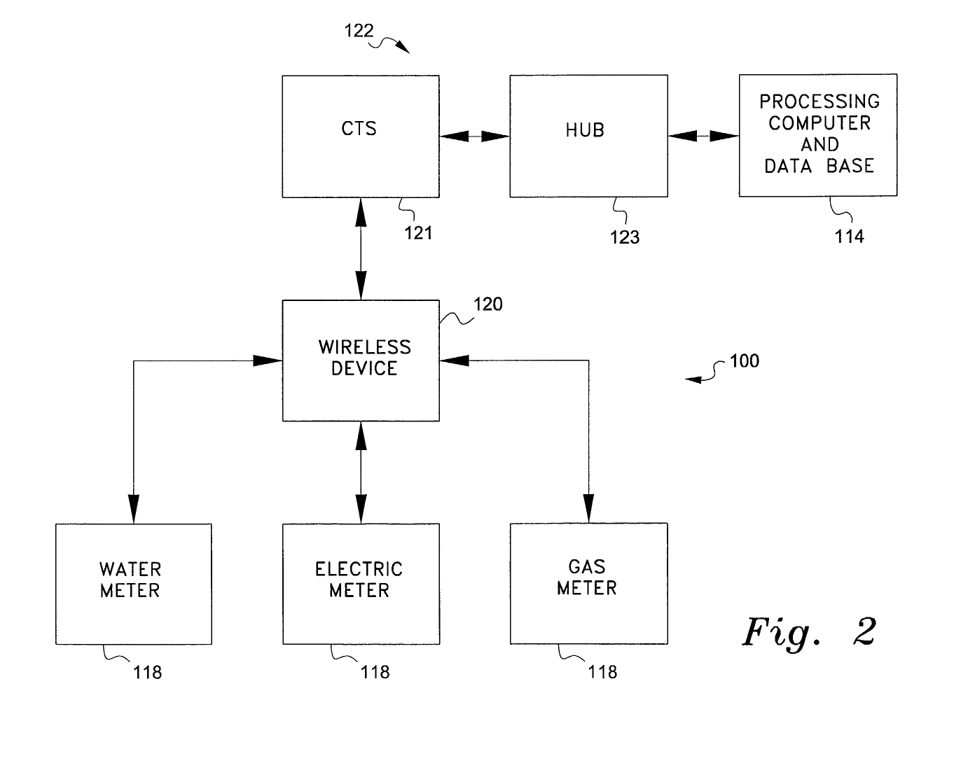

FIG. 2 shows a prepay utility service system 100 according to a second preferred embodiment of the invention. The second embodiment of the prepay utility service system 100 has substantially the same configuration as that recited earlier for the first preferred embodiment except in this case, a single remote transceiver unit 120 jointly serves a plurality of utility meters 118.

Accordingly, as shown in FIG. 2, the prepay utility service system 100 preferably includes a plurality of meters 118, a single remote transceiver unit 120, a first (wireless) network 122 that includes a cell transceiver site (CTS) 121 and a hub 123, and a processing center portion 114 that includes a computer processing unit and a database.

The system 100 is a new packet data system designed for inexpensive two-way network communications. The low cost of air time, combined with low installation and hardware cost, makes the system 100 an ideal solution for applications which do not benefit from traditional higher cost networking systems.

The system 100 has three main components, the hub 123, the cellsite transceiver stations (CTS) 121 and the remote transceiver units (RTU) 120. The hub 123 is the nerve center and brains of the system 100. This houses the communications hardware and software as well as the system's hardware and operating software. In addition, the hub 123 connects the system 100 to the overall network 130, as well as being the gateway between the application provider's equipment and his computer.

Specifically, the hub 123 monitors the system 100 and directs the activity of the individual CTSs 121 and RTUs 120. The CTSs 121 are linked direct to the hub 123 and are responsible for the RTUs 120 within their cell site. The RTUs 120 are the devices connected of meters 118, vending machines 124 and security system 125. The RTUs 120 receive data from the particular piece of equipment and sends information to the CTSs 121, which in turn sends it to the hub 123. Once the data has reached the hub 123, the hub 123 may hold the data for retrieval at a later time or it can immediately forward the data to its final destination.

The system 100 utilizes an overall network 130, which links all of the systems' wireless IP network together via the Internet or private network facility 132. This means that access to the wireless IP network markets is available anywhere. For example, a manager of vending machine operations can be in his office in Boston and directly monitor the operation of a specific machine at an airport in Los Angeles. Since the system 100 is two-way, the same manager can send new instructions to the specific machine as well.

The overall network 130 allows for seamless roaming between the systems 100 or markets. The previously discussed manager, can leave his office in Boston, get on an airplane to Los Angles, arrive and log on to the Los Angeles system and receive his messages or communicate with the Boston office.

The hub 123 controls all of the CTSs 121 within the system 100. The hub 123 receives transmission control protocol/Internet protocol (TCP/IP) data from client servers and routes the data to the appropriate CTS 121, which in turn passes the data to the appropriate RTU 120. Since the system 100 is two-way, the individual RTUs 120 pass their data to their respective CTS 121, which in turn passes the data to the hub, which then sends the data to the appropriate client server.

The entire system 100 is completely programmable from the hub 123, which monitors the system maintenance, administration and program controls. For example, the hub 123 can direct the CTS's 121 to change frequencies, increase or decrease power and change other predetermined parameters dynamically as network requirements and applications change.

The hub 123 is also the control center for a licensee network. One hub 123 can manage an entire service area. The hub 123 includes Internet software and hardware. By giving each hub 123 a direct Internet connection, all units in any service area can communicate with each other or the outside world. Applications and customers can directly access their RTUs 120 via the hub 123.

There is a centralized CTS 121 which is radio frequency (RF) linked to the RTUs 120 in its cell. The system 100 contains a number of CTSs 121, each managing a microcell of RTUs 120. The CTS 121 instructs the RTUs 120 assigned to it, passing information to the RTUs 120 and receiving data from the RTUs 120. The CTS 121 in turn receives its instructions from the hub 123.

In a mobile application, if a RTU 120 “roams” through a cell, the CTS 121 involved automatically sees the RTU 121 with no loss of service and continues the mobile RTU's 120 communication link. Physically, the CTS 120 is compact and light enough to mount almost anywhere. The CTS 120 communicates with the hub 123 over a dial-up network connection using point to point protocol (PPP). Each CTS 121 also has a battery back-up (not shown).

The RTUs 120 are small 2-way RF modems that are the key to making the system 100 a powerful communications network. Weighing approximately 4 ounces, the RTU 120 gives the power of remote monitoring without the bulk often associated with such devices. It fully supports serial and parallel connection protocols, and even supports PPP, allowing for transparent Internet access through its serial port (not shown). For demanding applications, where space is at a premium, the RTU 120 is available in an original equipment manufacturer (OEM) form, allowing custom hardware to piggyback on top of a given RTU board, resulting in an extremely small, yet powerful device.

It is to be understood that the present invention is not limited to the sole embodiments described above, but encompasses any and all embodiments within the scope of the following claims.

We claim:

1. A computerized prepay utility service system for facilitating prepayment of utility services by consumers, said prepay utility service system being communicatively connected to) each of a wireless Internet protocol (IP) network, a wired IP network, and a public telephone network, said prepay utility service system comprising:
a utility monitoring means for monitoring usage of utility services;
a processing means for processing data acquired by said client end portion; and
a remote client enabling means for enabling a client to create, modify, monitor, and terminate a utility services account.

2. The prepay utility services system recited in claim 1, wherein said utility monitoring means for monitoring comprises:
a plurality of utility meters for monitoring usage of utility services; and
a plurality of remote transceiver units, each of said plurality of remote transceiver units being communicatively connected to one of said utility meters for transmitting acquired data from the utility meter to the wireless IP network.

3. The prepay utility services system recited in claim 1, wherein said processing means for processing said client end portion comprises:
a computer processing unit for processing utility account data;
a database communicatively connected to said computer processing unit for storing utility account data.

4. The prepay utility services system recited in claim 1, wherein said remote client enabling means for enabling comprises:
a client computer communicatively linked to the wired IP network for enabling said client computer to access various utility accounts stored in said processing means.

5. The prepay utility services system recited in claim 1, wherein said remote client enabling means for enabling comprises:
a telephone apparatus communicatively connected to the public telephone network for enabling a consumer to access a utility service account stored in said processing means.

6. A wireless IP network, for facilitating prepayment of utility services by consumers, comprises:
a plurality of utility services meters, said meters determine the quantity of utility services and products used by a consumer;
a hub means for utilizing Internet hardware and software to receive TCP/IP data from a plurality of client servers;
a cell transmitter station means for communicating with the hub means over a dial-up network connection using PPP protocol; and
a remote transceiver unit means for communicating with the cell transmitter station means utilizing a transmitter, said remote transceiver unit means to interface with other devices using a PPP protocol.

7. The wireless IP network recited in claim 6, wherein said plurality of utility service meters include water meters, electric meters and natural gas meters.

8. The wireless IP network recited in claim 6, wherein said hub means is a personal computer.

9. The wireless IP network recited in claim 6, wherein said cell transmitter station means is a centralized cell transceiver station that is RF linked to RTUs in its cell.

10. The wireless IP network recited in claim 6, wherein said remote transceiver unit means is a two way synthesized transceiver and wireless device.
